(19) United States
(12) Patent Application Publication
(10) Pub. No.: US 2010/0271745 A1
(43) Pub. Date: Oct. 28, 2010

(54) ELECTROSTATIC CHUCK AND BASE FOR PLASMA REACTOR HAVING IMPROVED WAFER ETCH RATE

(75) Inventors: Jinyuan CHEN, Shanghai (CN); Liang Ouyang, Shanghai (CN); Junichi Arami, Shanghai (CN); Xueyu Qian, Shanghai (CN); Zhiyou Du, Shanghai (CN); Gerald Yin, Shanghai (CN)

Correspondence Address: NIXON PEABODY, LLP, 401 9TH STREET, NW, SUITE 900, WASHINGTON, DC, 20004-2128, US

(73) Assignee: ADVANCED MICRO-FABRICATION EQUIPMENT, INC. ASIA, Georgetown (KY)

(21) Appl. No.: 12/502,988

(22) Filed: Jul. 14, 2009

(30) Foreign Application Priority Data
Apr. 24, 2009 (CN) 200910049953.6

(51) Int. Cl. H01L 21/683; C23F 1/08; H05K 13/00

(52) U.S. Cl. 361/234; 156/345.43; 29/825

(57) ABSTRACT

An electrostatic chuck device in which the electrostatic chuck and support are made from high resistivity, high thermal conductivity and low RF energy loss dielectric materials is described. An advantage of this electrostatic chuck device is that the wafer surface electromagnetic field distribution is more uniform than conventional electrostatic chuck devices. As a result, the wafer etch rate, especially the wafer edge etch rate non-uniformity, is significantly improved compared with conventional electrostatic chuck devices.

### RELATED APPLICATIONS

This application claims priority from Chinese Patent Application Serial No. 200910049953.6, which was filed on Apr. 24, 2009, the entire disclosure of which is incorporated herein by reference.

### BACKGROUND

1. Field

The subject invention relates to an electrostatic chuck device for a plasma reactor.

2. Related Art

An exemplary electrostatic chuck device is illustrated in FIG. 1A. The electrostatic chuck device 100 is positioned in a plasma processing chamber (not shown) The conventional electrostatic chuck device 100 includes an electrostatic chuck 108 and a base 130. The electrostatic chuck 108 includes a support 140, an electrode 150 in the support 140 and a dielectric 160 overlying the support and the electrode. The base 130 includes RF inputs 164 and coolant channels 168. Pin lift holes 172 are provided that extend through the base 130 and electrostatic chuck 108. The substrate is positioned on an upper surface of the electrostatic chuck 108 (on a surface of the dielectric). A plasma process is performed on a surface of the substrate that is exposed to plasma in the plasma processing chamber.

In the plasma processing chamber, electromagnetic wavelengths are reduced by approximately a factor of 5 from its free space wavelength, such that its quarter wavelength may approach the dimensions of the plasma chamber. As a result, the plasma density across the reactor may no longer be uniform. For example, FIG. 1B illustrates the non-uniformity of the plasma density across a wafer for an electrostatic chuck that includes a metallic base 130 and metallic support 140). This standing wave phenomenon becomes more predominant in the chamber because the wavelength decreases as the free space excitation frequency increases.

Furthermore, the high frequency energy that results in a high plasma density can also reduce the skin depth. As a result, a skin effect may occur where maximum plasma heating occurs in the chamber (i.e., at the edge of the discharge).

It has also been found in examining some post-etch substrates that there exists a preferential edge effect, which renders the etch rate non-uniform across the substrate surface. The preferential edge effect shows a nontrivial increase in the etch rate at the substrate edge relative to other regions of the substrate, e.g., the center region.

Thus, the disparity in density of the plasma in the chamber causes variations of the processing parameters in the chamber, which results in inconsistent or non-uniform processing of substrates (e.g., plasma non-uniformity, wafer etch rate non-uniformity, and edge etch rate non-uniformity).

### SUMMARY

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

According to an aspect of the invention, a plasma reactor is provided that includes an enclosure; a plasma gas source to supply a plasma gas in the enclosure; a cathode pedestal coupled to the enclosure; a metallic base supported by the cathode pedestal; a support coupled to the metallic base; an electrostatic chuck coupled to the support and having an electrode therein, wherein the support and the electrostatic chuck each comprises a dielectric material having a high resistivity, high thermal conductivity and low radiofrequency (RF) energy loss; an RF source coupled to the metallic base to excite the plasma gas in the enclosure; and a DC voltage source coupled to the electrode to secure a wafer to the electrostatic chuck.

The support and the electrostatic chuck may be the same dielectric material.

The support and the electrostatic chuck may be different dielectric materials.

The dielectric material may be selected from the group consisting of SiC, ALN and Al₂O₃.

The thickness of the support and electrostatic chuck may be about 5-12 mm.

The thickness of the electrostatic chuck may be about 0.5-5 mm.

The resistivity of the dielectric material may be about 10¹⁰-10¹² ohms.

The plasma reactor may further include a silicon adhesive to bond the electrostatic chuck to the support.

The thickness of the adhesive may be less than about 10 μm.

According to another aspect of the invention, an electrostatic chuck device for a plasma reactor is provided that includes a metallic base; a support coupled to the metallic base; an electrostatic chuck coupled to the support and having an electrode therein, wherein the support and the electrostatic chuck each comprises a dielectric material having a high resistivity, high thermal conductivity and low radiofrequency (RF) energy loss.

The dielectric material may be selected from the group consisting of SiC, ALN and Al2O3.

The thickness of the support and electrostatic chuck may be about 5-12 mm.

The thickness of the electrostatic chuck may be about 1-5 mm.

The electrostatic chuck device may further include a silicon adhesive to bond the electrostatic chuck to the support.

The thickness of the adhesive may be less than about 10 μm.

According to yet another aspect of the invention, an electrostatic chuck device for a plasma reactor is provided that includes a metallic base; a support coupled to the metallic base, wherein the support comprises SiC or AlN; an electrostatic chuck coupled to the support, wherein the electrostatic chuck comprises Al2O3; and an electrode in the electrostatic chuck.

The thickness of the support and electrostatic chuck may be about 5-12 mm.

The thickness of the electrostatic chuck may be about 1-5 mm.

The electrostatic chuck device may further include a silicon adhesive to bond the electrostatic chuck to the support.

The thickness of the adhesive may be less than about 10 μm.

According to a further aspect of the invention, a method of fabricating an electrostatic chuck is provided, including coupling a support to a metallic base, wherein the support comprises dielectric material; coupling an electrostatic chuck to the support, wherein the electrostatic chuck comprises dielectric material, wherein the dielectric material of the support and the dielectric material of the electrostatic chuck are selected from the group consisting of SiC, ALN and Al2O3; and sintering an electrode in the electrostatic chuck.

The support and the electrostatic chuck may be the same dielectric material.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale.

FIG. 1A is a schematic view of a prior art electrostatic chuck;

FIG. 1B is a graph of the etch rate across a wafer using the chuck of FIG. 1A;

FIG. 2 is a schematic view of a plasma processing chamber in accordance with one embodiment;

FIG. 3A is a schematic view of an electrostatic chuck according to one embodiment of the invention; and

FIG. 3B is a graph of the etch rate across a wafer using the chuck of FIG. 3B.

### DETAILED DESCRIPTION

Embodiments of the invention relate to an electrostatic chuck device in which the electrostatic chuck and separate support member are made from high resistivity, high thermal conductivity and low RF energy loss dielectric materials. An advantage of this electrostatic chuck device is that the wafer surface electromagnetic field distribution is more uniform than the distribution for conventional electrostatic chuck devices. As a result, the wafer etch rate, and especially the wafer edge etch rate non-uniformity, is significantly improved.

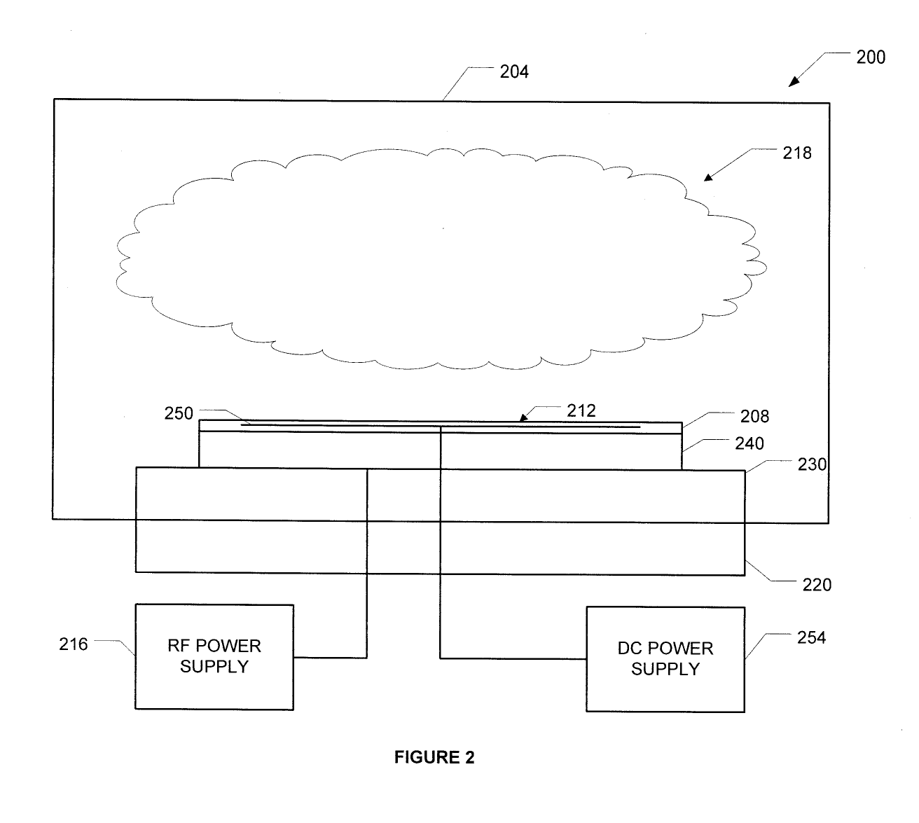

An embodiment of the invention will now be described in detail with reference to FIG. 2. FIG. 2 illustrates a plasma processing apparatus 200 according to one embodiment of the invention. It will be appreciated that the apparatus 200 is merely exemplary and that the apparatus 200 may include fewer or additional components and the arrangement of the components may differ from that illustrated in FIG. 2.

The plasma processing apparatus 200 includes a chamber 204 and an electrostatic chuck 208 in the chamber 204. A wafer (not shown) is disposed in the chamber 204 and on the surface 212 of the electrostatic chuck 208. A gas source (not shown) supplies gas into the chamber 204 which is excited by an RF power supply 216 to generate plasma 218. The electrostatic chuck 208 is supported by a cathode pedestal 220 that supports a base 230 and a support member 240. The electrostatic chuck 208 includes an electrode 250 therein. A DC power supply 254 is coupled to the electrode 250 to apply a voltage to the electrode 250 to chuck and dechuck the wafer from the electrostatic chuck 208.

In use, the RF power supply 216 generates the plasma 220 and a high DC voltage is applied by the DC power supply 254 to the electrode 250 to chuck the wafer to the electrostatic chuck 208. After the wafer is chucked, a plasma processing operation may be performed in the chamber 104. After processing is completed, the RF power supply 216 is turned off and the wafer is, then, dechucked by applying a reverse DC voltage to the electrode 250 using the DC power supply 254.

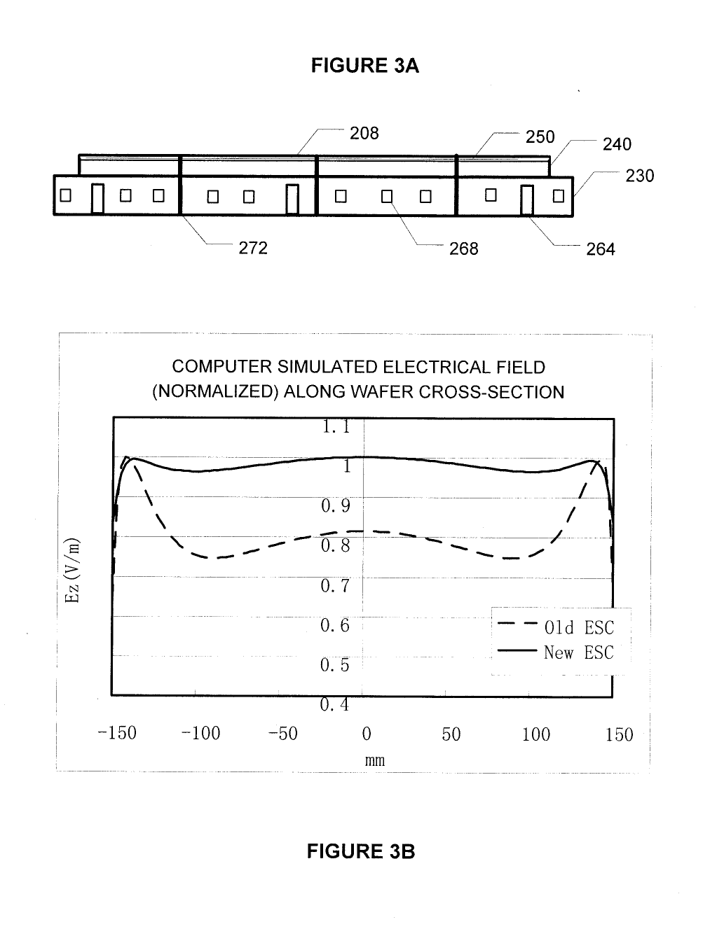

FIG. 3A illustrates the electrostatic chuck device 110 according to one embodiment of the invention. The electrostatic chuck device 110 includes the base 230, the support member 240 and the electrostatic chuck 208. As shown in FIG. 3A, the base 230 includes RF inputs 264 and coolant channels 268. Pin lift holes 272 are provided that extend through the base 230, support member 240 and the electrostatic chuck 208. As described above, a substrate is positionable on an upper surface of the electrostatic chuck 208.

In the embodiment shown in FIG. 3A, the support member 240 and the electrostatic chuck 208 are made from high resistivity, high thermal conductivity and low RF loss dielectric materials. In one embodiment, the resistivity of the material is about 10¹⁰-10¹² ohms. Exemplary materials include SiC, AlN, Al₂O₃ and the like. It will be appreciated, however, that other ceramic materials may be used that have high resistivity, high thermal conductivity and low loss.

In one embodiment, the support member 240 and the electrostatic chuck 208 are made from the same material. It will be appreciated that the support member 240 and the electrostatic chuck 208 may be made from different materials each of which is a high resistivity, high thermal conductivity and low RF loss dielectric materials. In embodiments in which the support member 240 and the electrostatic chuck 208 are made from the same material, the pieces may be formed integrally.

In embodiments in which the support member 240 and the electrostatic chuck 208 are made from different materials, the pieces may be bonded together. For example, a silicon adhesive may join the support member 240 and the electrostatic chuck 208 together. The support member 240 may also be bonded to the base 230. The same silicon adhesive may be used to join the support member 240 with the base 230.

In one particular embodiment, the support member 240 is made from SiC or AlN and the electrostatic chuck 208 is made from Al₂O₃. The electrode 250 is sintered in the electrostatic chuck 208.

In one embodiment, the thickness of the support member 240 and electrostatic chuck 208 is any value or range of values between about 5-12 mm, and the thickness of the electrostatic chuck 208 is about 0.5-5 mm. In one particular embodiment, the electrostatic chuck may be about 1 mm thick. The thickness of the electrode 250 is less than or equal to about 0.5 mm. In embodiments in which the electrostatic chuck 208 and the support member 240 are bonded together with an adhesive, the thickness of the adhesive is about 8 μm.

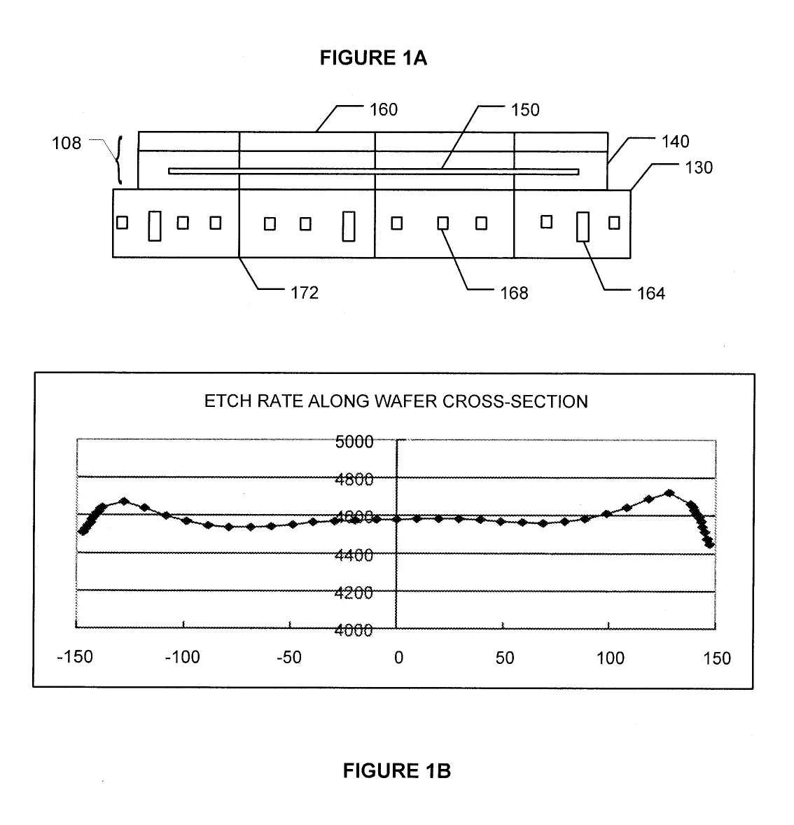

FIG. 3B illustrates the electric field along a wafer cross-section with the electrostatic chuck 208 of FIG. 3A compared with a conventional electrostatic chuck 108 of FIG. 1A. As shown in FIG. 3B, the uniformity of the electric field with the electrostatic chuck 208 of FIG. 3A is significantly improved compared with the conventional electrostatic chuck 108 of FIG. 1A.

It should be understood that processes and techniques described herein are not inherently related to any particular apparatus and may be implemented by any suitable combination of components. Further, various types of general purpose devices may be used in accordance with the teachings described herein. The present invention has been described in relation to particular examples, which are intended in all respects to be illustrative rather than restrictive. Those skilled in the art will appreciate that many different combinations will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A plasma reactor comprising:
an enclosure;
a plasma gas source to supply a plasma gas in the enclosure;
a cathode pedestal coupled to the enclosure;
a metallic base supported by the cathode pedestal;
a support coupled to the metallic base;
an electrostatic chuck coupled to the support and having an electrode therein,
wherein the support and the electrostatic chuck each comprises a dielectric material having a high resistivity, high thermal conductivity and low radiofrequency (RF) energy loss;
an RF source coupled to the metallic base to excite the plasma gas in the enclosure; and
a DC voltage source coupled to the electrode to secure a wafer to the electrostatic chuck.

2. The plasma reactor of claim 1, wherein the support and the electrostatic chuck comprise the same dielectric material.

3. The plasma reactor of claim 1, wherein the support and the electrostatic chuck comprise different dielectric materials.

4. The plasma reactor of claim 1, wherein the dielectric material is selected from the group consisting of SiC, ALN and Al₂O₃.

5 . The plasma reactor of claim 1, wherein the thickness of the support and electrostatic chuck is about 5-12 mm.

6. The plasma reactor of claim 1, wherein the thickness of the electrostatic chuck is about 0.5-5 mm.

7. The plasma reactor of claim 1, wherein the resistivity of the dielectric material is about 10¹⁰-10¹² ohms.

8. The plasma reactor of claim 1, further comprising a silicon adhesive to bond the electrostatic chuck to the support.

9. The plasma reactor of claim 8, wherein the thickness of the adhesive is less than about 10 μm.

10. An electrostatic chuck device for a plasma reactor comprising:
a metallic base;
a support coupled to the metallic base;
an electrostatic chuck coupled to the support and having an electrode therein,
wherein the support and the electrostatic chuck each comprises a dielectric material having a high resistivity, high thermal conductivity and low radiofrequency (RF) energy loss.

11. The electrostatic chuck device of claim 10, wherein the dielectric material is selected from the group consisting of SiC, ALN and Al₂O₃.

12. The electrostatic chuck device of claim 10, wherein the thickness of the support and electrostatic chuck is about 5-12 mm.

13. The electrostatic chuck device of claim 10, wherein the thickness of the electrostatic chuck is about 1-5 mm.

14. The electrostatic chuck device of claim 10, further comprising a silicon adhesive to bond the electrostatic chuck to the support.

15. The electrostatic chuck device of claim 10, wherein the thickness of the adhesive is less than about 10 μm.

16. An electrostatic chuck device for a plasma reactor comprising:
a metallic base;
a support coupled to the metallic base, wherein the support comprises SiC or AlN;
an electrostatic chuck coupled to the support, wherein the electrostatic chuck comprises Al₂O₃; and
an electrode in the electrostatic chuck.

17. The electrostatic chuck device of claim 16, wherein the thickness of the support and electrostatic chuck is about 5-12 mm.

18. The electrostatic chuck device of claim 16, wherein the thickness of the electrostatic chuck is about 1-5 mm.

19. The electrostatic chuck device of claim 16, further comprising a silicon adhesive to bond the electrostatic chuck to the support.

20. The electrostatic chuck device of claim 19, wherein the thickness of the adhesive is less than about 10 μm.

21. A method of fabricating an electrostatic chuck comprising:
coupling a support to a metallic base, wherein the support comprises dielectric material;
coupling an electrostatic chuck to the support, wherein the electrostatic chuck comprises dielectric material, wherein the dielectric material of the support and the dielectric material of the electrostatic chuck are selected from the group consisting of SiC, ALN and Al₂O₃; and
sintering an electrode in the electrostatic chuck.

22. The method of claim 21, wherein the support and the electrostatic chuck comprise the same dielectric material.
